(19) United States
(12) Patent Application Publication
(10) Pub. No.: US 2022/0328514 A1
(43) Pub. Date: Oct. 13, 2022

(54) SEMICONDUCTOR MEMORY DEVICE AND METHOD OF MANUFACTURING THE SAME

(71) Applicant: SK hynix Inc., Icheon-si Gyeonggi-do (KR)

(72) Inventors: Dong Uk LEE, Icheon-si Gyeonggi-do (KR); Hae Chang YANG, Icheon-si Gyeonggi-do (KR)

(73) Assignee: SK hynix Inc., Icheon-si Gyeonggi-do (KR)

(21) Appl. No.: 17/348,560

(22) Filed: Jun. 15, 2021

(30) Foreign Application Priority Data
Apr. 9, 2021 (KR) 10-2021-0046303

(51) Int. Cl. H01L 27/11582; H01L 29/51; H01L 21/02; H01L 21/28

(52) U.S. Cl. CPC H01L 27/11582; H01L 29/513; H01L 29/517; H01L 21/022; H01L 21/02178; H01L 21/0234; H01L 29/40117

(57) ABSTRACT

A semiconductor memory device includes a gate stack structure and a plurality of channel structures. The gate stack structure includes an insulating interlayer and a gate conductive layer that are alternately stacked. The plurality of channel holes is formed in the gate stack structure. The plurality of channel holes includes a fluorine-containing layer, a first blocking layer, and a charge-trapping layer. The fluorine-containing layer is formed on surfaces of the channel holes for forming the plurality of channel structures. The first blocking layer is formed on the fluorine-containing layer along the surfaces of the channel holes. The charge-trapping layer is formed on the first blocking layer along the surfaces of the channel holes.

### CROSS-REFERENCES TO RELATED APPLICATION

The present application claims priority under 35 U.S.C. § 119(a) to Korean application number 10-2021-0046303, filed on Apr. 9, 2021, in the Korean Intellectual Property Office, which is incorporated herein by reference in its entirety.

### TECHNICAL FIELD

Various embodiments may generally relate to an electronic device, more particularly to a semiconductor memory device and a method of manufacturing the semiconductor memory device.

### BACKGROUND

In order to satisfy good performance and low cost demanded by users, it may be required to improve an integration degree of a semiconductor device. Particularly, an integration degree of a semiconductor memory device may be an important factor for determining the performance and the cost of the semiconductor memory device. Thus, the improvements of the integration degree have been continuously developed. For example, in a semiconductor memory device including a plurality of memory cells, a three-dimensional semiconductor memory device has been studied. The three-dimensional semiconductor memory device may include a plurality of memory cells that are arranged in a three-dimensional structure to reduce the area of the memory cells that occupies a unit area of a substrate.

### SUMMARY

In example embodiments of the present disclosure, a semiconductor memory device may include a gate stack structure and a plurality of channel structures. The gate stack structure may include an insulating interlayer and a gate conductive layer that are alternately stacked. Each of the plurality of channel structures may be formed in the gate stack structure. Each of the plurality of channel structures includes a fluorine-containing layer, a first blocking layer, and a charge-trapping layer. The fluorine-containing layer may be formed on surfaces of channel holes for forming the channel structures. The first blocking layer may be formed on the fluorine-containing layer along the surfaces of the channel holes. The charge-trapping layer may be formed on the first blocking layer along the surfaces of the channel holes.

In example embodiments of the present disclosure, a semiconductor memory device may include a gate stack structure and a plurality of channel structures. Each of the plurality of channel structures includes a charge-trapping layer, a tunnel insulation layer, a fluorine-containing layer, and a channel layer. The gate stack structure may include an insulating interlayer and a gate conductive layer that are alternately stacked. Each of the plurality of channel structures may be formed in the gate stack structure. The charge-trapping layer may be formed on a surface of a channel hole, among a plurality of channel holes, to form the channel structures. The tunnel insulation layer may be formed on the charge-trapping layer along the surfaces of the channel holes. The fluorine-containing layer may be formed on the tunnel insulation layer along the surfaces of the channel holes. The channel layer may be formed on the fluorine-containing layer along the surfaces of the channel holes.

In example embodiments of the present disclosure, a semiconductor memory device may include a gate stack structure and a plurality of channel structures. Each of the plurality of channel structure includes a memory layer, a first fluorine-containing layer, a channel layer and a second fluorine-containing layer. The gate stack structure may include an insulating interlayer and a gate conductive layer that are alternately stacked. The insulation interlayer may include a plurality of fluorine ions. For forming the channel structures, the plurality of channel structures may be formed in the gate stack structure. The memory layer may be formed on surfaces of the channel holes. The memory layer may include a first blocking layer, a charge-trapping layer, and a tunnel insulation layer that are sequentially stacked. The first fluorine-containing layer may be interposed between the gate stack structure and the first blocking layer. The channel layer may be formed on the tunnel insulation layer along the surfaces of the channel holes. The second fluorine-containing layer may be interposed between the channel layer and the tunnel insulation layer.

In example embodiments of the present disclosure, according to a method of manufacturing a semiconductor memory device, an insulating interlayer and a gate conductive layer may be alternately stacked to form a stack. The stack may be selectively etched to form a plurality of channel holes. A first fluorine-containing layer may be formed on surfaces of the channel holes. A first blocking layer may be formed on the first fluorine-containing layer along the surfaces of the channel holes. A charge-trapping layer and a tunnel insulation layer may be sequentially formed on the first blocking layer along the surfaces of the channel holes. A surface treatment may be performed on a surface of the tunnel insulation layer to absorb a plurality of fluorine ions on the surface of the tunnel insulation layer. A second fluorine-containing layer may be formed on the tunnel insulation layer along the surfaces of the channel holes. A channel layer may be formed on the second fluorine-containing layer along the surfaces of the channel holes.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a block diagram illustrating a semiconductor memory device in accordance with example embodiments;

FIG. 2 is a circuit diagram illustrating a memory block of a semiconductor memory device in accordance with example embodiments;

FIG. 3 is a perspective view illustrating a semiconductor memory device in accordance with example embodiments;

FIG. 4 is a cross-sectional view illustrating a semiconductor memory device in accordance with example embodiments;

FIG. 5 is an enlarged cross-sectional view of a portion “A” in FIG. 4;

FIG. 6 is a cross-sectional view illustrating a semiconductor memory device in accordance with example embodiments corresponding to the portion “A” in FIG. 4;

FIGS. 7A to 7E are cross-sectional views illustrating a method of manufacturing a semiconductor memory device in accordance with example embodiments;

FIG. 8 is a block diagram illustrating a memory system memory device in accordance with example embodiments; and

FIG. 9 is a block diagram illustrating a computing system in accordance with example embodiments.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

Example embodiments may provide a semiconductor memory device with improved reliability and a method of manufacturing the semiconductor memory device. Particularly, the semiconductor memory device and the method of manufacturing the semiconductor memory device may have the improved reliability by preventing a loss of programmed data under a condition that the semiconductor memory device may be continuously exposed to a high temperature environment. The semiconductor memory device may include a non-volatile memory device with a three-dimensional structure based on a charge trap, for example, a three-dimensional NAND.

When the semiconductor memory device is used for a vehicle, a plurality of IR (Infrared)-reflows may be performed with data being programmed. The IR-reflow may be a semiconductor packaging process performed by an IR-treatment at a high temperature. When the IR-reflow is performed at a high temperature, the programmed data may be lost. For example, when the semiconductor memory device based on the charge trap is continuously exposed to the high temperature environment, the programmed data may be lost by thermal emissions of trapped charges to deteriorate data maintenance characteristics. Thus, it may be required to prevent the reliability of the semiconductor memory device from being reduced caused by the loss of the programmed data due to the high temperature environment.

Example embodiments may include implanting fluorine ions into a memory layer and a structure configured to make contact with the memory layer, which may be configured to store data or charges, to suppress movements of mobile ions, and to prevent the loss of the programmed data at a high temperature environment.

Hereinafter, the semiconductor memory device and the method of manufacturing the semiconductor memory device in accordance with example embodiments may be illustrated in detail. In example embodiments, a first direction D1, a second direction D2 and a third direction D3 may be substantially perpendicular to each other. For example, the first direction D1 may be an X-direction, the second direction D2 may be a Y-direction and the third direction D3 may be a Z-direction in an XYZ coordinate.

Example embodiments provide a semiconductor memory device with improved reliability.

Example embodiments also provide a method of manufacturing the above-mentioned semiconductor memory device.

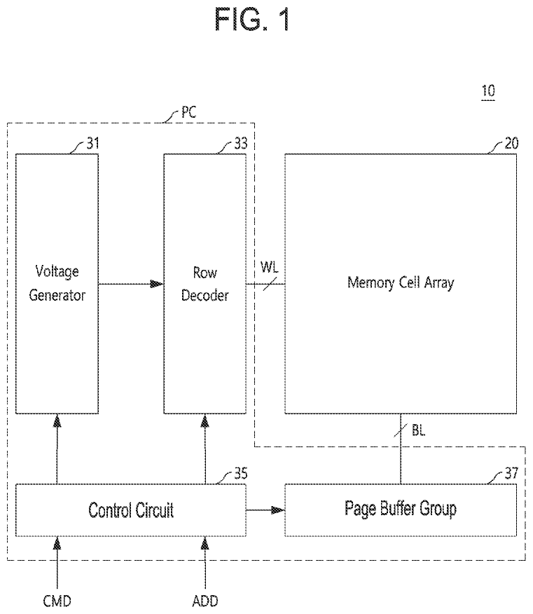

FIG. 1 is a block diagram illustrating a semiconductor memory device in accordance with example embodiments.

Referring to FIG. 1, a semiconductor memory device 10 may include a peripheral circuit PC and a memory cell array 20.

The peripheral circuit PC may be configured to control a program operation for storing data in the memory cell array 20, a read operation for outputting the data in the memory cell array 20, and an erase operation for erasing the data in the memory cell array 20. For example, the peripheral circuit PC may include a voltage generator 31, a row decoder 33, a control circuit 35, and a page buffer group 37.

The memory cell array 20 may include a plurality of memory blocks. The memory cell array 20 may be connected with the row decoder 33 through word lines WL. The memory cell array 20 may be connected with the page buffer group 37 through bit lines BL.

The control circuit 35 may be configured to control the peripheral circuit PC in response to a command CMD and an address ADD.

The voltage generator 31 may be configured to generate various operational voltages, such as a pre-erase voltage, an erase voltage, a ground voltage, a program voltage, a verification voltage, a pass voltage, a read voltage, etc., used in the program operation, the read operation, and the erase operation in response to the control circuit 35.

The row decoder 33 may be configured to select the memory block in response to the control circuit 35. The row decoder 33 may apply the operational voltages to the word lines WL connected to the selected memory block.

The page buffer group 37 may be connected with the memory cell array 20 through the bit lines BL. The page buffer group 37 may be configured to temporarily store data that is received from an input/output circuit in the program operation in response to the control circuit 35. The page buffer group 37 may sense a voltage or a current of the bit lines BL in the read operation or the verification operation in response to the control circuit 35. The page buffer group 37 may select the bit lines BL in response to the control circuit 35.

The memory cell array 20 and the peripheral circuit PC may be placed on the same plane, side by side. Alternatively, the memory cell array 20 and the peripheral circuit PC may be arranged to partially overlap on different planes.

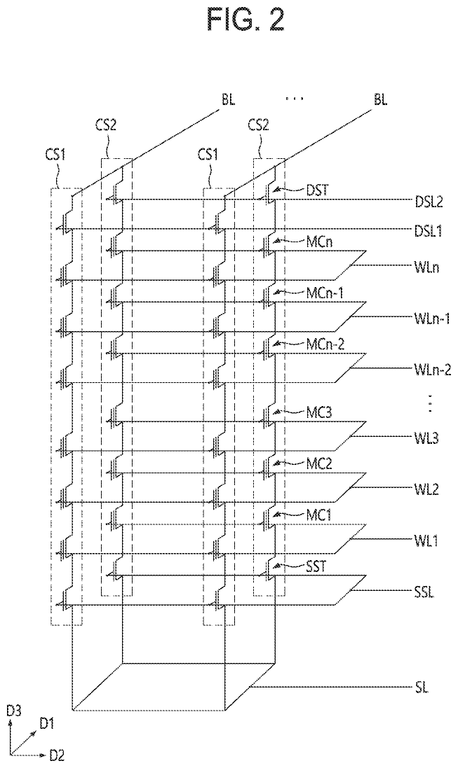

FIG. 2 is a circuit diagram illustrating a memory block of a semiconductor memory device in accordance with example embodiments.

Referring to FIG. 2, the memory block may include a plurality of cell strings CS1 and CS2 that are connected to a source layer SL and word lines WL1˜WLn, in common.

Each of the cell strings CS1 and CS2 may include at least one source selection transistor SST, at least one drain selection transistor DST, and a plurality of memory cells MC1˜MCn. The source selection transistor SST may be connected to the source layer SL. The drain selection transistor DST may be connected to the bit line BL. The plurality of memory cells MC1˜MCn may be connected between the source selection transistor SST and the drain selection transistor DST, in series.

The gates of the memory cells MC1˜MCn may be connected to the stacked word lines WL1˜WLn, respectively, spaced apart from each other along the third direction D3. The word lines WL1˜WLn may be arranged between a source selection line SSL and at least two drain selection lines DSL1 and DSL2. The drain selection lines DSL1 and DSL2 may be spaced apart from each other on the same level.

In example embodiments, the cell strings CS1 and CS2 may be connected to one source selection line SSL. However, the embodiments of the present disclosure are not limited thereto. Alternatively, the source selection line SSL may include a plurality of conductive lines that are spaced apart from each other on the same level or a plurality of stacked conductive lines that are spaced apart from each other along the third direction D3.

The gate of the source selection transistor SST may be connected to the source selection line SSL. The gate of the drain selection transistor DST may be connected to the drain selection line that corresponds to the gate of the drain selection transistor DST.

The source layer SL may be connected to the source selection transistor SST. The drain of the drain selection transistor DST may be connected to the bit line BL that corresponds to the drain of the drain selection transistor DST.

The plurality of cell strings CS1 and CS2 may be classified into a plurality of string groups that are connected to the at least two drain selection lines DSL1 and DSL2, respectively. The cell strings that are connected to the same word line and the same bit line may be independently controlled by the different drain selection lines. Further, the cell strings that are connected to the same drain selection line may be independently controlled by the different bit lines. For example, the at least two drain selection lines DSL1 and DSL2 may include a first drain selection line DSL1 and a second drain selection line DSL2. The cell strings CS1 and CS2 may include a first string group of a first cell string CS1 that is connected to the first drain selection line DSL1, and a second string group of a second cell string CS2 that are connected to the second drain selection line DSL2.

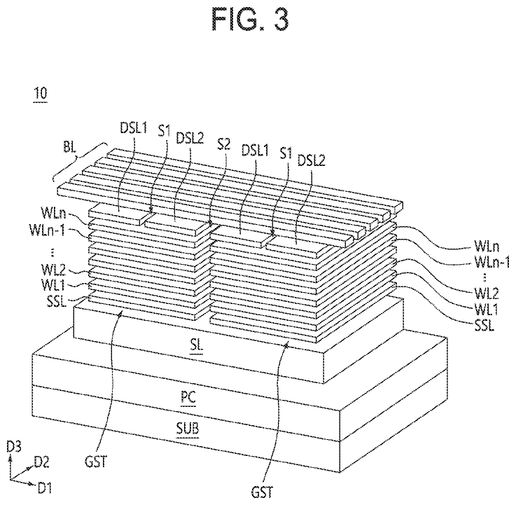

FIG. 3 is a perspective view illustrating a semiconductor memory device in accordance with example embodiments.

Referring to FIG. 3, the semiconductor memory device 10 may include the peripheral circuit PC that is arranged on a substrate SUB and gate stack structures GST that overlap with the peripheral circuit PC.

Each of the gate stack structures GST may include the source selection line SSL, the plurality of the word lines WL1˜WLn, and the drain selection line. The drain selection line may be separated into at least two drain selection lines DSL1 and DSL2 by a first slit S1. The drain selection lines DSL1 and DSL2 may be placed on the same plane.

The source selection line SSL and the word lines WL1˜WLn may be expanded along the first direction D1 and the second direction D2. The source selection line SSL and the word lines WL1˜WLn may have a flat plate shape that is arranged on an upper surface of the substrate SUB, side by side.

The word lines WL1˜WLn may be spaced apart from each other along the third direction D3. Thus, the word lines WL1˜WLn may overlap with each other along the direction D3. The word lines WL1˜WLn may be arranged between the at least two drain selection lines DSL1 and DSL2 and the source selection line SSL.

The gate stack structures GST may be divided by a second slit S2. The length of the first slit S1 along the third direction D3 may be shorter than the length of the second slit S2 along the third direction D3. The first slit S1 may overlap (positioned) with the word lines WL1˜WLn.

Each of the first and second slits S1 and S2 may be extended in a straight shape, a zigzag shape, a wave shape, etc., along the second direction D2. Each of the first and second slits S1 and S2 may have a width that is changed in accordance with a design rule.

The source selection line SSL may be arranged to be adjacent to the peripheral circuit PC. The semiconductor memory device 10 may include the source layer SL and the bit lines BL. The source layer SL may be arranged between the gate stack structures GST and the peripheral circuit PC. The bit lines BL may be positioned remote from the peripheral circuit PC than the source layer SL. The gate stack structures GST may be arranged between the bit lines BL and the source layer SL.

The bit lines BL may include various conductive layers, such as a doped semiconductor layer, a metal layer, a metal alloy layer, etc. The source layer SL may include a doped semiconductor layer. For example, the source layer SL may include an N type doped silicon layer.

Although not depicted in drawings, the peripheral circuit PC may be electrically connected with the bit lines BL, the source layer SL, and the word lines WL1˜WLn through interconnections with various structures.

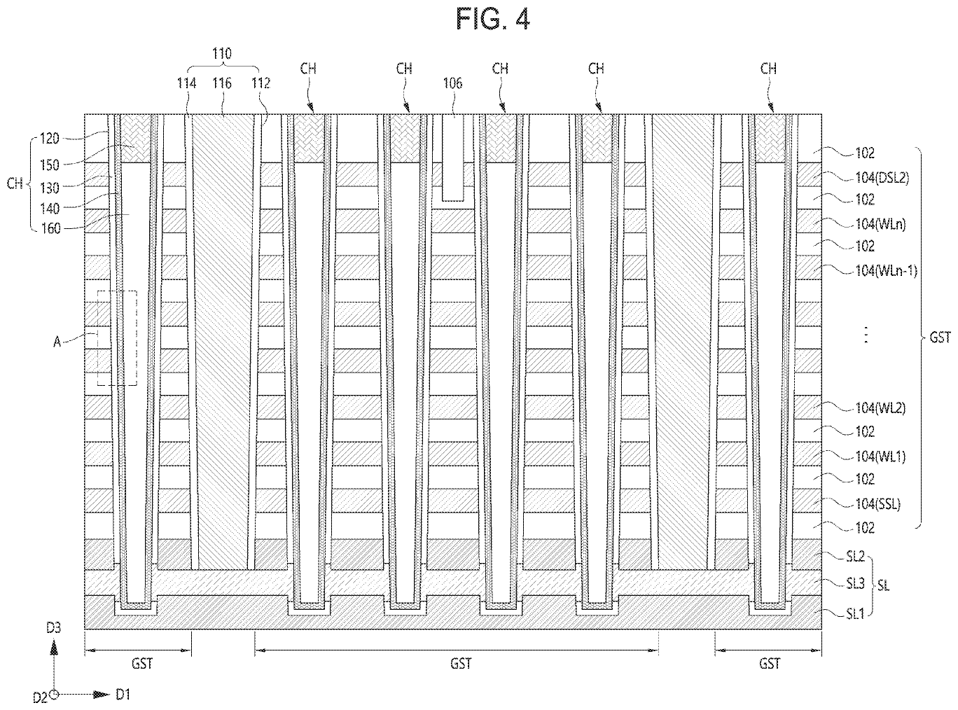

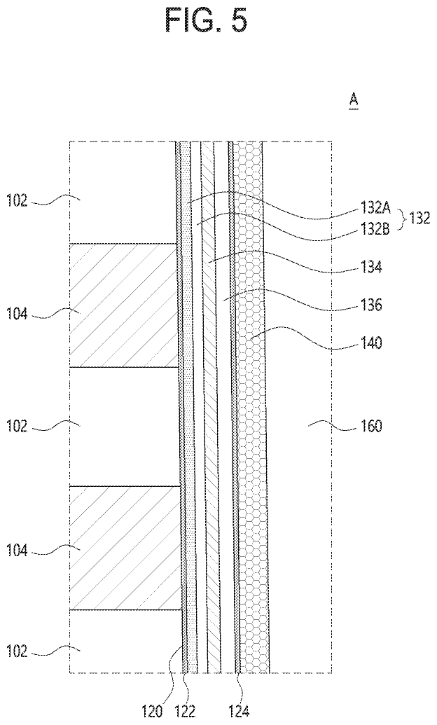

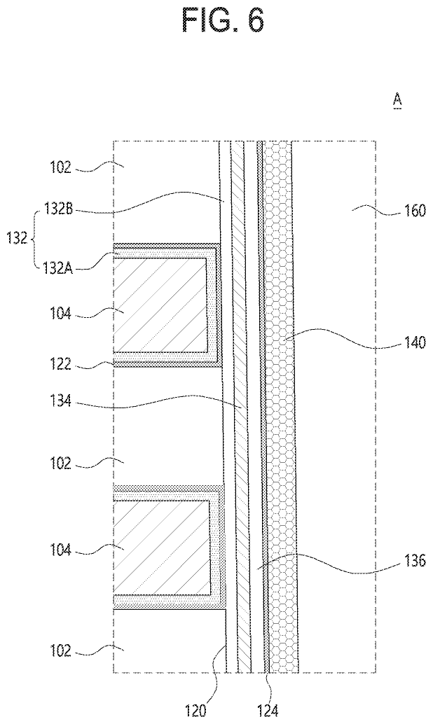

FIG. 4 is a cross-sectional view illustrating a semiconductor memory device in accordance with example embodiments, FIG. 5 is an enlarged cross-sectional view of a portion “A” in FIG. 4, and FIG. 6 is a cross-sectional view illustrating a semiconductor memory device in accordance with example embodiments corresponding to the portion “A” in FIG. 4.

Referring to FIGS. 4 and 5, the semiconductor memory device of example embodiments may include the source layer SL, the gate stack structures GST, a slit structure 110, and a plurality of channel structures CH. The gate stack structures GST may be formed on the source layer SL. The slit structures 110 may be formed between the gate stack structures GST. The channel structures CH may be formed through the gate stack structures GST.

The source layer SL may overlap with the gate stack structures GST. The source layer SL may have a flat plate shape that is extended in the first and second directions D1 and D2. The source layer SL may include a first source layer SL1, a third source layer SL3, and a second source layer SL2 that are sequentially stacked. That is, the third source layer SL3 may be interposed between the first source layer SL1 and the second source layer SL2. The third source layer SL3 may be electrically connected to a channel layer 140 of each of the channel structures CH.

Each of the gate stack structures GST may be divided by the slit structures 110. Particularly, the slit structures 110 may be positioned on both sidewalls of each of the gate stack structures GST in the first direction D1. Each of the gate stack structures GST that is divided by the slit structures 110 may correspond to one memory block. The source layer SL may be positioned under the gate stack structures GST. The bit lines, in FIG. 3, may be positioned over the gate stack structures GST. Thus, the source layer SL, the gate stack structures GST, and the bit lines may overlap with each other.

In example embodiments, the source layer SL may be positioned under the gate stack structures GST, and the bit lines may be positioned over the gate stack structures GST. However, the embodiments of the present disclosure are not limited thereto. Alternatively, the bit lines may be positioned over the gate stack structures GST and the source layer SL may be positioned under the gate stack structures GST.

Further, the gate stack structures GST may have a single layered structure along the third direction D3. However, the embodiments of the present disclosure are not limited thereto. Alternatively, the at least two gate stack structures GST may be stacked along the third direction D3.

Each of the slit structures 110 may correspond to the second slit S2 in FIG. 3. Each of the slit structures 110 may have a line pattern that is extended in the second direction D2. In example embodiments, each of the slit structures 110 may be extended in a straight shape, a zigzag shape, a wave shape, etc., along the second direction D2. A lower end of each of the slit structures 110, in the third direction D3, may have a shape that is expanded into the source layer SL. For example, the slit structure 110 may have a bottom surface that is configured to make contact with the third source layer SL3 between the first source layer SL1 and the second source layer SL2.

Each of the slit structures 110 may include a slit trench 112, a slit spacer 114, and a slit layer 116. The slit trench 112 may have a line shape that is extended in the second direction D2. The slit spacer 114 may be formed on both sidewalls of the slit trench 112 in the first direction D1. The slit layer 116 may be configured to fully fill the slit trench 112. The slit spacer 114 may include an insulation material. The slit layer 116 may include a conductive material.

In example embodiments, the slit layer 116 may include the conductive material. However, the embodiments of the present disclosure are not limited thereto. Alternatively, the slit layer 116 may include an insulation material.

Each of the gate stack structures GST may include an insulating interlayer 102 and a gate conductive layer 140 that are alternately stacked. The insulating interlayer 102 may be positioned at an uppermost layer and a lowermost layer in the gate stack structure GST. The insulating interlayer at the uppermost layer in the gate stack structure GST may have a thickness that is thicker than the thicknesses of other insulating interlayers 102. The insulating interlayer 102 and the gate conductive layer 104 may have a flat plate shape that is extended in the first and second directions D1 and D2.

The insulating interlayer 102 may include an oxide layer, a nitride layer, an oxynitride layer, etc. In order to improve the data retention at a high temperature environment, the insulating interlayer 102 may include an insulation layer with a plurality of fluorine ions (F). The fluorine ions may have a negative charge. For example, the insulating interlayer 102 may include a silicon oxide layer with the fluorine ions that have a negative charge.

The fluorine ions in the insulating interlayer 102 may cure a defect in and on the insulating interlayer 102, such as a vacancy, a dangling bond, etc., to suppress a trap that is caused by the defect. For example, when the insulating interlayer 102 includes the silicon oxide layer, the fluorine ion may be coupled with an oxygen vacancy or a silicon dangling bond to form a silicon-fluorine (Si—F) bond. Thus, the defect in and on the insulating interlayer 102 may be cured to suppress the trap that is caused by the defect. The suppression of the trap by curing the defect may mean that the trap may be deactivated to prevent the trap from being moved to a site for trapping a charge.

Further, the fluorine ions in the insulating interlayer 102 may prevent the abnormal change in the threshold voltage in the memory cell due to a mobile ion with a positive charge. Particularly, during the repeating of the program operation and the erase operation, the mobile ions in the insulating interlayer 102 may be accumulated around a memory layer 130 and a channel layer to change or shift a threshold voltage distribution of the memory cell. The fluorine ions in the insulating interlayer 102 may suppress the movements of the mobile ions to prevent the mobile ions from being accumulated in the peripheral regions of the memory layer 130 and the channel layer 140. Further, although the mobile ions may be accumulated in the peripheral regions of the memory layer 130 and the channel layer 140 of each of the memory cells, the fluorine ions with the negative charge may electrically neutralize the mobile ions to prevent the threshold voltage distribution of the memory cell from being changed.

The gate conductive layer 104 may include a conductive layer with a metal. For example, the gate conductive layer 104 may include a tungsten layer. Alternatively, the gate conductive layer 104 may include a titanium nitride layer and a tungsten layer that are sequentially stacked. The titanium nitride layer may act as a barrier layer to prevent diffusions of tungsten.

The gate conductive layer at the lowermost layer of each of the gate stack structures GST may act as a gate of the source selection transistor SST in FIG. 2 and the source selection line SSL in FIGS. 2 and 3.

In example embodiments, the gate conductive layer 104 that acts as the gate of the source selection transistor and the source selection line may include a single layered structure. However, the embodiments of the present disclosure are not limited thereto. Alternatively, a plurality of the gate conductive layers 104 that are positioned at a lower portion of the gate stack structure GST, including the lowermost gate conductive layer 104, may be used for the gate of the source selection transistor and the source selection line.

In example embodiments, the lowermost gate conductive layer 104 in each of the gate stack structures GST that acts as the source selection line may have one pattern on the same level. However, the embodiments of the present disclosure are not limited thereto. Alternatively, the lowermost gate conductive layer 104 in each of the gate stack structures GST that acts as the source selection line may have at least two patterns that are spaced apart from each other on the same level.

The uppermost gate conductive layer 104 in each of the gate stack structures GST may act as a gate of the drain selection transistor DST in FIG. 2 and the drain selection lines DSL1 and DSL2 in FIGS. 2 and 3. The uppermost gate conductive layer 104 in each of the gate stack structures GST may be divided into at least two patterns, which may be spaced apart from each other on the same level, by at least one isolation layer 106. The isolation layer 106 may correspond to the first slit S1 in FIG. 3. Thus, the gate conductive layer 104 that is positioned at one end and the other end of the isolation layer 106 along the first direction D1 may correspond to the first drain selection line DSL1 and the second drain selection line DSL2 in FIG. 3. The isolation layer 106 may include an insulation layer, such as an oxide layer, a nitride layer, an oxynitride layer, etc.

In example embodiments, the gate conductive layer 104 that acts as the gate of the drain selection transistor and the drain selection lines may include a single layered structure. However, the embodiments of the present disclosure are not limited thereto. Alternatively, a plurality of the gate conductive layers 104 that are positioned at an upper portion of the gate stack structure GST, including the uppermost gate conductive layer 104, may be used for the gate of the drain selection transistor and the drain selection lines.

Each of the gate conductive layers 104 in each of the gate stack structures GST between the gate conductive layer 104 that acts as the source selection line and the gate conductive layer 104 that acts as the drain selection line may act as a gate of the memory cell transistor and the word line. Thus, the gate conductive layers 104 between the uppermost gate conductive layer 104 and the lowermost gate conductive layer 104 in each of the gate stack structures GST may correspond to the word lines WL1˜WLn in FIG. 3.

The channel structures CH may be arranged in the gate stack structure GST in a matrix shape. The planar shape of each of the channel structures CH may be a polygonal shape, a circular shape, an elliptical shape, etc. Each of the channel structures CH may have a pillar shape that is extended in the third direction D3. Further, each of the channel structures CH may have a high aspect ratio. Thus, each of the channel structures CH may have a trapezoidal cross-sectional shape with gradually decreased widths from an upper end to a lower end in the channel structure along the third direction D3.

Each of the channel structures CH may be formed through the gate stack structure GST. Each of the channel structures CH may include a lower end that is extended into the source layer SL. Particularly, the lower end of the channel structure CH may penetrate through the first source layer SL1 and the third source layer SL3. The lower end of the channel structure CH may have a bottom surface that is positioned in the first source layer SL1. Each of the channel structures CH may be electrically connected with the source layer SL through the lower end of the channel structure CH that is extended into the source layer SL.

When the at least two gate stack structures GST is stacked along the third direction D3, the channel structure CH may also have a stack structure that is similar to the gate stack structures GST. For example, when the two gate stack structures GST is stacked along the third direction D3, the two channel structures CH may also be stacked along the third direction D3 that corresponds to each of the gate structures GST.

Each of the channel structures CH may include a channel hole 120, a memory layer 130, a first fluorine-containing layer 122, a channel layer 140, a second fluorine-containing layer 124, an insulation core 160, and a capping layer 150. The channel hole 120 may be formed at the gate stack structure GST. The memory layer 130 may be formed on a surface of the channel hole 120. The first fluorine-containing layer 122 may be interposed between the gate stack structure GST and the memory layer 130. The channel layer 140 may be formed on the memory layer 130 along the surface of the channel hole 120. The second fluorine-containing layer 124 may be interposed between the memory layer 130 and the channel layer 140. The insulation core 160 may be formed on the channel layer 140 to partially fill the channel hole 120. The capping layer 150 may be formed on the insulation core 160 to fully fill the channel hole 120. The memory layer 130 may include a blocking layer 132, a charge-trapping layer 134, and a tunnel insulation layer 136 that are sequentially stacked. The blocking layer 132 may be configured to make contact with the first fluorine-containing layer 122. The tunnel insulation layer 136 may be configured to make contact with the second fluorine-containing layer 124.

The insulation core 160 may have a pillar shape that is configured to penetrate the gate stack structure GST. The insulation core 160 may have a lower end that is extended into the source layer SL. The insulation core 160 may include an insulation layer, such as an oxide layer, a nitride layer, an oxynitride layer, etc. For example, the insulation core 160 may include the oxide layer.

The capping layer 150 may have a pillar shape that is positioned on the insulation core 160. The capping layer 150 may act as a source or a drain of the drain selection transistor DST in FIG. 2. An interface between the insulation core 160 and the capping layer 150 may be aligned with a surface of the uppermost gate conductive layer 104 in the gate stack structure GST. Alternatively, the interface between the insulation core 160 and the capping layer 150 may be positioned on a plane that is higher than a plane on which the surface of the uppermost gate conductive layer 104 may be positioned. The uppermost gate conductive layer 104 in the gate stack structure GST may correspond to the gate of the drain selection transistor DST in FIG. 2. The capping layer 150 may be electrically connected to the channel layer 140. The capping layer 150 may include a doped semiconductor layer. For example, the capping layer 150 may include an N type doped silicon layer.

In example embodiments, the channel layer 140 may be configured to surround the capping layer 150. However, the embodiments of the present disclosure are not limited thereto. Alternatively, the channel layer 140 may have a cylindrical shape that is configured to surround a side surface and a bottom surface of the insulation core 160. An upper end of the cylindrical channel layer 140 may be configured to make contact with a bottom surface of the capping layer 150.

The tunnel insulation layer 136 may have a cylindrical shape that is configured to surround a side surface and a bottom surface of the channel layer 140. The tunnel insulation layer 136 may include an oxide layer, a nitride layer, an oxynitride layer, etc. For example, the tunnel insulation layer 136 may include the oxide layer or an oxide layer with the fluorine ions. For example, the tunnel insulation layer 136 may include a silicon oxide layer or a silicon oxide layer with the fluorine ions.

Alternatively, the tunnel insulation layer 136 may include an oxide layer that is doped with nitrogen, i.e., the oxynitride layer or an oxynitride layer with the fluorine ions. The nitrogen in the oxynitride layer may increase a height of a potential barrier of the oxide layer. The high height of the potential barrier in the tunnel insulation layer 136 may prevent the abnormal changes of the threshold voltage in the memory cell that are caused by an electron emission from the trap at an edge portion of a conduction band through a band gap engineering. For example, the tunnel insulation layer 136 may include a silicon oxide layer that is doped with nitrogen, i.e., a silicon oxynitride layer or a silicon oxynitride layer with the fluorine ions.

When the tunnel insulation layer 136 includes the oxide layer with the fluorine ions or the oxynitride layer with the fluorine ions, the fluorine ions may cure the defects in and on the tunnel insulation layer 136 and on a structure that makes contact with the tunnel insulation layer 135 such as the channel layer 140 and the charge-trapping layer 134 to suppress the trap caused by the defects. When the tunnel insulation layer 136 includes the oxynitride layer with the fluorine ions, the fluorine ions may cure the defect, such as a grid defect caused by the nitrogen, by suppressing the trap that is caused by the defects.

The fluorine ions in the tunnel insulation layer 136 may cure the defect at the interface between the tunnel insulation layer 136 and the charge-trapping layer 134 to suppress the tap that is caused by the defect or to decrease a trap level. Particularly, the fluorine ions in the tunnel insulation layer 135 may convert a deep trap at the interface between the tunnel insulation layer 136 and the charge-trapping layer 134 into a shallow trap. The deep trap that is generated at the interface between the tunnel insulation layer 136 and the charge-trapping layer 134 may increase a generation probability of a trap assisted tunneling (TAT) due to an interaction of the trap level in the tunnel insulation layer 136. However, the fluorine ions may convert the deep trap into a shallow trap to reduce the generation probability of a TAT.

The second fluorine-containing layer 124 that is interposed between the tunnel insulation layer 136 and the channel layer 140 in the memory layer 130 may reduce the trap that is generated in the interface between the channel layer 140 and the tunnel insulation layer 136, i.e., the density of an interface trap, to improve the data maintenance characteristic at a high temperature environment. Further, the second fluorine-containing layer 124 may decrease the density of the interface trap between the channel layer 140 and the tunnel insulation layer 136 to suppress the generation of a leakage current and to decrease the generation probability of a TAT. The second fluorine-containing layer 124 may include at least one element that is substantially the same as an element of the channel layer 140. For example, when the channel layer 140 includes a silicon layer, the second fluorine-containing layer 124 may include a fluoric silicon layer (SiFx).

When the tunnel insulation layer 136 includes an oxide layer with fluorine ions or an oxynitride layer with fluorine ions, the fluorine ions in the tunnel insulation layer 135 may be formed by diffusing the fluorine ions in the second fluorine-containing layer 124 into the tunnel insulation layer 136.

The charge-trapping layer 134 in the memory layer 130 may provide a space that is configured to store charges that act as data. The charge-trapping layer 134 may have a cylindrical shape that is configured to surround the side surface and the bottom surface of the tunnel insulation layer 136. The charge-trapping layer 134 may include an oxide layer, a nitride layer, an oxynitride layer, etc. When the tunnel insulation layer 135 and a second blocking layer 132B include fluorine ions, the fluorine ions in the tunnel insulation layer 136 and the second blocking layer 132B may diffuse into the charge-trapping layer 134 to improve the data maintenance characteristics of the charge-trapping layer 134.

The blocking layer 132 in the memory layer 130 may prevent a charge tunneling between the gate conductive layer 104 and the charge-trapping layer 134. The blocking layer 132 may have a cylindrical shape that is configured to surround a side surface and a bottom surface of the charge-trapping layer 132. The blocking layer 132 may include an oxide layer, a nitride layer, an oxynitride layer, a combination thereof, etc. For example, the blocking layer 132 may include a multi-layer with different oxide layers that are sequentially stacked. Particularly, the blocking layer 132 may include a first blocking layer 132A that is configured to make contact with the first fluorine-containing layer 122 and a second blocking layer 132B that is configured to make contact with the charge-trapping layer 134.

The first blocking layer 132A may include an insulation layer with a high dielectric. For example, the first blocking layer 132A may include a metal oxide layer. Particularly, the first blocking layer 132A may include an aluminum oxide layer (Al₂O₃), a hafnium oxide layer (HfO₂), etc.

The second blocking layer 132B may include a semiconductor oxide layer. Particularly, the second blocking layer 132B may include a semiconductor oxide layer with fluorine ions. The fluorine ions in the second blocking layer 132B may cure the defects in and on the second blocking layer 132B and the defects on the structures that make contact with the second blocking layer 132B, such as the first blocking layer 132A and the charge-trapping layer 134 to suppress the trap that is caused by the defects. For example, the second blocking layer 132B may include a silicon oxide layer with the fluorine ions.

In example embodiments, the blocking layer 132 may include multiple layers, i.e., a multi-layer. However, the embodiments of the present disclosure are not limited thereto. Alternatively, the blocking layer 132 may include only one of the first blocking layer 132A and the second blocking layer 132B. For example, the blocking layer 132 may include only the second blocking layer 132B.

The first fluorine-containing layer 122 that is interposed between the blocking layer 132 in the memory layer 130 and the gate stack structure GST may reduce the trap that is generated in the interface between the blocking layer 132 and the gate stack structure GST to improve the data maintenance characteristic at a high temperature environment. The first fluorine-containing layer 122 may include at least one element that is substantially the same as an element of the first blocking layer 132A. Particularly, when the first blocking layer 132A includes the metal oxide layer, the first fluorine-containing layer 122 may include a metal oxyfluoride layer. The metal oxide layer and the metal oxyfluoride layer may include substantially the same metal. For example, when the first blocking layer 132A includes an aluminum oxide layer (Al₂O₃), the first fluorine-containing layer 122 may include aluminum oxyfluoride layer (AlOxFy).

In example embodiments, the first fluorine-containing layer 122, the first blocking layer 132A, and the second blocking layer 132B may be arranged in the channel hole 120. However, the embodiments of the present disclosure are not limited thereto. Alternatively, the first fluorine-containing layer 122 and the first blocking layer 132A may be positioned in the gate stack structure GST, and the second blocking layer 132B may be located in the channel hole 120. Particularly, the second blocking layer 132B may be formed on the surface of the channel hole 120 to have a cylindrical shape. The first fluorine-containing layer 122 and the first blocking layer 132A may be interposed between the insulating interlayer 102 and the gate conductive layer 104 and between the gate conductive layer 104 and the second blocking layer 132B. The first fluorine-containing layer 122 may be configured to make contact with the insulating interlayer 102 and the second blocking layer 132B. The second blocking layer 132B may be configured to make contact with the gate conductive layer 104.

Further, in example embodiments, the channel structure CH may include the first fluorine-containing layer 122 and the second fluorine-containing layer 124. However, the embodiments of the present disclosure are not limited thereto. Alternatively, the channel structure CH may include only one of the first fluorine-containing layer 122 and the second fluorine-containing layer 124.

According to example embodiments, the first fluorine-containing layer 122 may decrease the interface trap density that is generated in the interface between the gate stack structure GST and the blocking layer 132.

Further, the second fluorine-containing layer 124 may decrease the interface trap density that is generated in the interface between the tunnel insulation layer 136 and the channel layer 140 to suppress the generation of the leakage current and to reduce the generation probability of a TAT.

Furthermore, defects in the memory layer 130 and the adjacent structures may be cured by the fluorine ions to suppress the trap that is caused by the defects, thereby improving the data maintenance characteristics under a high temperature environment.

Moreover, the insulating interlayer 102 with the fluorine ions may prevent the threshold voltage distribution of the memory cell from being changed by the mobile ions. The three-dimensional semiconductor memory device may have uniform characteristics regardless of the height.

Therefore, the loss of the programmed data may be effectively prevented under the condition that the semiconductor memory device may be continuously exposed to the high temperature environment to provide the semiconductor memory device with improved reliability.

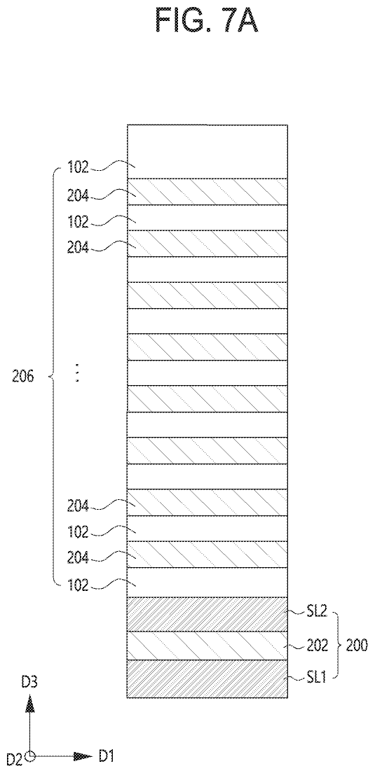

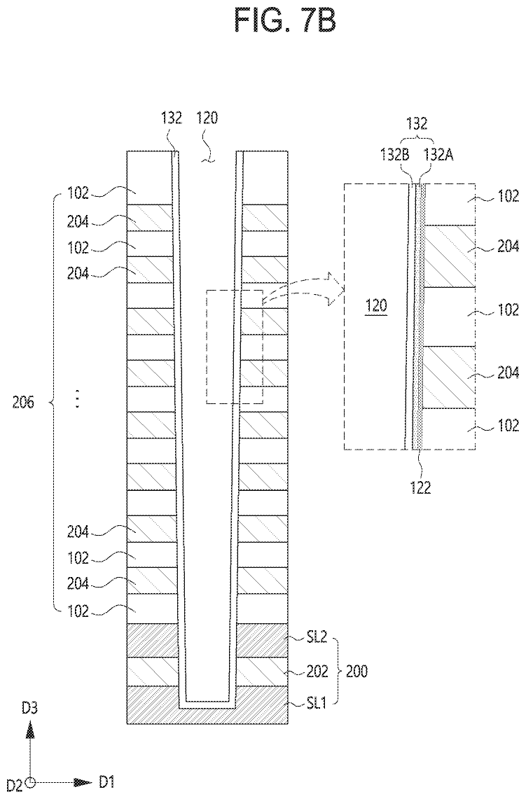

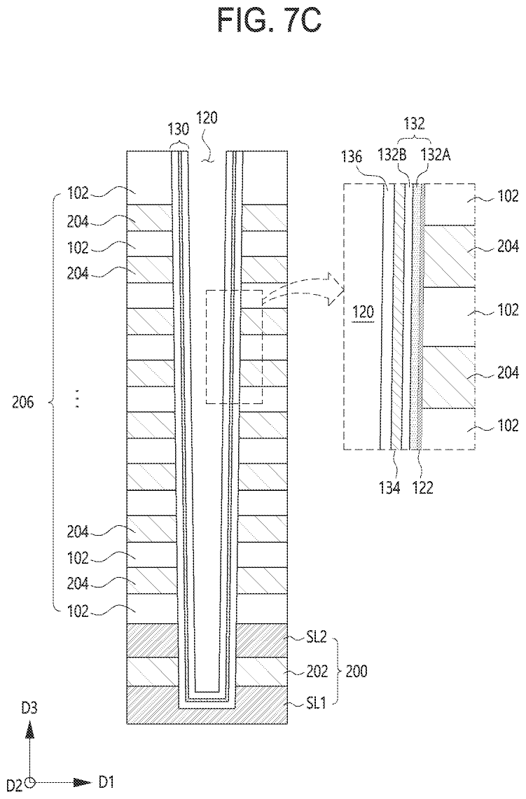

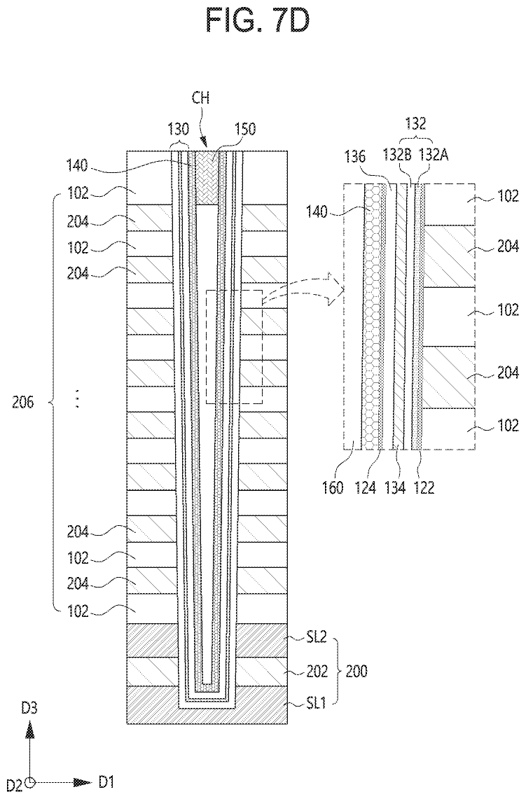

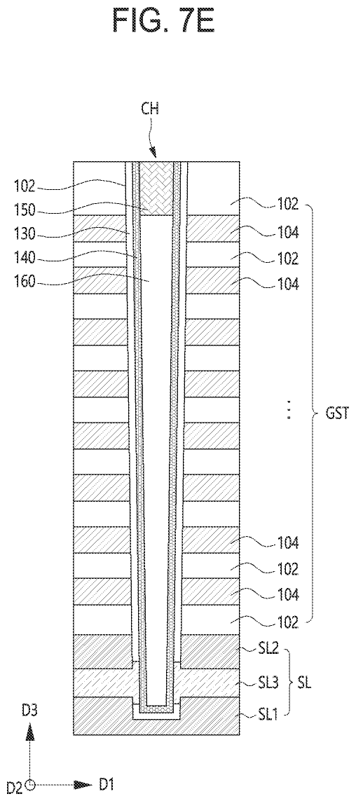

FIGS. 7A to 7E are cross-sectional views illustrating a method of manufacturing a semiconductor memory device in accordance with example embodiments. The same reference numerals may refer to the same elements in FIGS. 4 and 5 and any further illustrations with respect to the same elements may be omitted herein for brevity.

Referring to FIG. 7A, a preliminary source layer 200 may be formed on a substrate with the peripheral circuit PC in FIGS. 1 and 3. The preliminary source layer 200 may include a first source layer SL1, a source sacrificial layer 202, and a second source layer SL2 that are sequentially stacked. The preliminary source layer 200 may have a flat plate shape that is extended in the first direction D1 and the second direction D2. The first source layer SL1 and the second source layer SL2 may include N type doped silicon layers. The source sacrificial layer 202 may include a material with an etching selectivity with respect to the first source layer SL1 and the second source layer SL2. For example, the source sacrificial layer 202 may include an oxide layer, a nitride layer, an oxynitride layer, a combination thereof, etc. For example, the source sacrificial layer 202 may include the oxide layer.

A stack structure 206 may be formed on the preliminary source layer 200. The stack structure 206 may include an insulating interlayer 102 and a gate sacrificial layer 204 that are alternately stacked. The insulating interlayer 102 may be positioned at a lowermost layer and an uppermost layer in the stack structure 206. The uppermost insulating interlayer 102 in the stack structure 206 may have a thickness that is thicker than thicknesses of other layers in the stack structure 206. The gate sacrificial layer 204 may include a material with an etching selectivity with respect to the insulating interlayer 102. The insulating interlayer 102 and the gate sacrificial layer 204 may include an oxide layer, a nitride layer, an oxynitride layer, etc. A plurality of the insulating interlayers 102 in the stack structure 206 may include a plurality of fluorine ions. For example, the insulating interlayer 102 may include a silicon oxide layer with the fluorine ions. The gate sacrificial layer 204 may include a silicon nitride layer.

The silicon oxide layer with the fluorine ions may be formed by simultaneously supplying a silicon source gas, an oxygen gas and a fluorine gas into a chamber. The pure fluorine gas (F₂), not a fluorine-containing gas, such as a BF₃ gas, may be used as a reaction gas to prevent the silicon oxide layer from including unnecessary impurities. The remaining components in the fluorine-containing gas, except for the fluorine, may cause a defect in the silicon oxide layer. Alternatively, the silicon oxide layer with the fluorine ions may be formed by forming the silicon oxide layer and by implanting the fluorine ions into the silicon oxide layer. Further, the silicon oxide layer with the fluorine ions may be formed by forming the silicon oxide layer and by performing an annealing process under a fluorine gas atmosphere to diffuse the fluorine ions into the silicon oxide layer.

The fluorine ions in the insulating interlayer 102 may suppress the defects that are generated inside and on the surface of the insulating interlayer 102, such as the trap that is caused by vacancy, dangling bond, etc. Further, the fluorine ions in the insulating interlayer 102 may prevent the abnormal change of the threshold voltage in the memory cell by the mobile ions with the positive charge. The amount of fluorine ions in each of the insulating interlayers 102 of the stack structure 206, i.e., doped amounts of the fluorine ions, may be same. The fluorine ions may be implanted into the insulating interlayers 102 during the formation of the stack structure 206 to uniformly distribute the fluorine ions in each of the insulating interlayers 102 regardless of the height of the semiconductor memory device.

Referring to FIG. 7B, a hard mask pattern may then be formed on the stack structure 206. The stack structure 206 and the preliminary source layer 200 may be etched by using the hard mask pattern as an etch mask to form the channel hole 120. The channel hole 120 may be formed through the stack structure 206, the second source layer SL2, and the source sacrificial layer 202. An end of the channel hole 120 may be extended into the first source layer SL1.

Although not depicted in drawings, before forming the channel hole 120, the isolation layer in FIG. 4 may be formed through an uppermost gate sacrificial layer 204 in the stack structure 206 to divide the uppermost gate sacrificial layer 204 into at least two patterns. The isolation layer may correspond to the first slit S1 in FIG. 3. The isolation layer may include an insulation layer. For example, the isolation layer may include an oxide layer.

The first fluorine-containing layer 122 may be formed on the surface of the channel hole 120. The first blocking layer 132A may be formed on the first fluorine-containing layer 122. The first fluorine-containing layer 122 may cure the defect that is generated on the surface of the channel hole 120 to suppress the trap that is caused by the defect, thereby improving the data maintenance characteristic. That is, the first fluorine-containing layer 122 may decrease the surface trap density of the channel hole 120.

The first blocking layer 132A may include an oxide layer, a nitride layer, an oxynitride layer, etc. Particularly, the first blocking layer 132A may include the metal oxide layer with the high dielectric constant. The first blocking layer 132A may include an aluminum oxide layer, a hafnium oxide layer, etc.

The first fluorine-containing layer 122 may be formed by partially neutralizing the first blocking layer 132A. Thus, the first fluorine-containing layer 122 may include the at least one component that is included in the first blocking layer 132A. Particularly, when the first blocking layer 132A includes the metal oxide layer, the first fluorine-containing layer 122 may include the metal oxyfluoride layer. The metal oxide layer and the metal oxyfluoride layer may include the same component. For example, when the first blocking layer 132A includes the aluminum oxide layer, the first fluorine-containing layer 122 may include the aluminum oxyfluoride layer.

The first fluorine-containing layer 122 and the first blocking layer 132A may be formed through an atomic layer deposition (ALD) process. The first fluorine-containing layer 122 may be formed by supplying the fluorine gas into the chamber in an initial step for forming the first blocking layer 132A. Particularly, the first fluorine-containing layer 122 may be formed by repeatedly performing a first unit cycle. The first unit cycle may include applying a metal source gas, such as an aluminum source gas, purging, applying an oxygen gas, purging, applying the fluorine gas, and purging. The first blocking layer 132A may be formed by repeatedly performing a second unit cycle after forming the first fluorine-containing layer 122. The second unit cycle may include applying a metal source gas, purging, applying an oxygen gas, and purging.

The second blocking layer 132B may be formed on the first blocking layer 132A along the surface of the channel hole 120. The second blocking layer 132B may prevent the charge tunneling together with the first blocking layer 132A. The second blocking layer 132B may include a semiconductor oxide layer. Particularly, the second blocking layer 132B may include a semiconductor oxide layer with the fluorine ions. The fluorine ions in the second blocking layer 132B may cure the defects that are generated inside and on the surface of the second blocking layer 132B and on the surface of the structure that is adjacent to the second blocking layer 132B to suppress the trap caused by the defect. The second blocking layer 132B may include a silicon oxide layer with the fluorine ions.

The second blocking layer 132B may be formed through an ALD process. When the second blocking layer 132B includes the silicon oxide layer with the fluorine ions, the second blocking layer 132B may be formed by repeatedly performing a unit cycle including applying a silicon source gas, purging, applying an oxygen gas, purging, applying the fluorine gas, and purging.

Therefore, the blocking layer 132 with the first fluorine-containing layer 122, the first blocking layer 132A, and the second blocking layer 132B may be formed.

Referring to FIG. 7C, the charge-trapping layer 134 may be formed on the blocking layer 132 along the surface of the channel hole 120. The charge-trapping layer 134 may include an oxide layer, a nitride layer, an oxynitride layer, etc. For example, the charge-trapping layer 134 may include the nitride layer.

The tunnel insulating layer 136 may be formed on the charge-trapping layer 134 along the surface of the channel hole 120. The tunnel insulation layer 136 may include an oxide layer, an oxynitride layer, etc. For example, the tunnel insulation layer 136 may include a silicon oxide layer.

Alternatively, the tunnel insulation layer 136 may include a silicon oxide layer that is doped with nitrogen, i.e., a silicon oxynitride layer. The nitrogen in the oxynitride layer may control the potential barrier height of the oxide layer to prevent the abnormal change of the threshold voltage in the memory cell.

A surface treatment may be performed to absorb the fluorine ions on the surface of the tunnel insulation layer 136 to decrease the surface trap density of the interface between the channel layer 140 and the tunnel insulation layer 136. For example, the surface treatment may include a fluorine plasma treatment. Particularly, the fluorine plasma treatment may include introducing the fluorine gas into the chamber with a plasma atmosphere and absorbing the fluorine ions that are ionized by the plasma in the surface of the tunnel insulation layer 136. The fluorine ions that are absorbed on the surface of the tunnel insulation layer 136 may be bonded with the defect on the tunnel insulation layer 136, for example, a dangling bond to cure the defect on the tunnel insulation layer 136.

During the fluorine plasma treatment, the plasma may ionize the fluorine gas. However, the fluorine gas might not accelerate the fluorine gas so that the fluorine gas might not diffuse into the tunnel insulation layer 136. Thus, in order to absorb the fluorine ions only on the surface of the tunnel insulation layer 136, the surface of the tunnel insulation layer 136 may be treated with the fluorine plasma treatment.

Alternatively, when the tunnel insulation layer 136 with the fluorine ions is formed by absorbing the fluorine ions on the surface of the tunnel insulation layer and by simultaneously diffusing the fluorine ions into the tunnel insulation layer 136, the surface treatment may include an annealing process. Particularly, the annealing process may include supplying a mixed gas with an inert gas and the fluorine gas to the chamber at a temperature that is higher than 400° C. and a pressure that is higher than the atmospheric pressure. For example, the annealing process may include supplying a mixed gas with an inert gas and the fluorine gas to the chamber at a temperature of approximately 400° C. to 600° C. and under an atmosphere pressure to 3 torr. When an annealing temperature is below approximately 400° C., the fluorine ions might not be generated from the fluorine gas due to low thermal energy. Further, although the fluorine ions may be generated, the fluorine ions might not diffuse into the tunnel insulation layer 136. In contrast, when the annealing temperature is below the atmosphere pressure, the fluorine ions might not be absorbed on the surface of the tunnel insulation layer at a lower end of the channel hole 120. Further, the fluorine ions might not diffuse into the tunnel insulation layer 136.

The fluorine ions in the second blocking layer 132B in the annealing process may be moved to the interface between the second blocking layer 132B and the charge-trapping layer 134 to effectively cure the defect that is generated at the interface.

Thus, when the surface treatment that uses the annealing process is completed, the tunnel insulation layer 136 that includes the silicon oxide layer with the fluorine ions or the silicon oxynitride layer with the fluorine ions may be formed.

As a result, the memory layer 130 with the blocking layer 132, the charge-trapping layer 134, and the tunnel insulation layer 136 that are sequentially stacked may be formed.

Referring to FIG. 7D, the second fluorine-containing layer 124 may be formed on the tunnel insulation layer 136 along the surface of the channel hole 120. The channel layer 140 may then be formed on the second fluorine-containing layer 124. The second fluorine-containing layer 124 may cure the defect that is generated at the interface between the channel layer 140 and the tunnel insulation layer 136 to suppress the trap that is caused by the defect, thereby improving the data maintenance characteristic at a high temperature environment. That is, the second fluorine-containing layer 124 may decrease the surface trap density of the interface between the channel layer 140 and the tunnel insulation layer 136. Further, the second fluorine-containing layer 124 may suppress the generation of the leakage current and decrease the generation probability of a TAT.

The channel layer 140 may include a semiconductor layer. For example, the channel layer 140 may include a silicon layer. The second fluorine-containing layer 124 may be formed by partially fluoridizing the channel layer 140. That is, the second fluorine-containing layer 140 may be formed due to the reaction between the fluorine ions on the channel layer 140 and the tunnel insulation layer 136. Thus, the second fluorine-containing layer 124 may include the at least one element that is included in the channel layer 140. For example, when the channel layer 140 includes the silicon layer, the second fluorine-containing layer 124 may include the silicon oxyfluoride layer.

The second fluorine-containing layer 124 and the channel layer 140 may be formed through an ALD process. The second fluorine-containing layer 124 and the channel layer 1240 may be formed by repeatedly performing a cycle that includes introducing a silicon source gas into the chamber and purging. The fluorine ions on the tunnel insulation layer 136 may react with the silicon source gas in an initial step to form the second fluorine-containing layer 124. After the fluorine ions on the tunnel insulation layer 136 are completely consumed, the channel layer 140 may then be formed by repeating a unit cycle.

The insulation core 160 may be formed on the channel layer 140 to partially fill the channel hole 120. The capping layer 150 may then be formed on the insulation core 160 to fully fill the channel hole 120.

Therefore, the channel structure CH may be formed. The channel structure CH may include the memory layer 130, the second fluorine-containing layer 124, the channel layer 140, the insulation core 160, and the capping layer 150. The memory layer 130 may include the channel hole 120, the first fluorine-containing layer 122, the blocking layer 132, the charge-trapping layer 134, and the tunnel insulation layer 136.

Referring to FIGS. 4 and 7E, a hard mask pattern may be formed on the stack structure 206 with the channel structure CH. The stack structure 206 and the preliminary source layer 200 may be etched by using the hard mask pattern as an etch mask to form a slit trench 112. The source sacrificial layer 202 may be exposed through a bottom surface of the slit trench 112.

The gate sacrificial layer 204 may then be removed through the slit trench 112. The gate conductive layer 104 may be formed in a space that is formed by removing the gate sacrificial layer 204. The gate conductive layer 104 may include a conductive layer with a metal. For example, the gate conductive layer 104 may include tungsten. Alternatively, the gate conductive layer 104 may include a titanium layer and a tungsten layer that are sequentially stacked.

As a result, the gate stack structure GST with the insulating interlayer 102 and the gate conductive layer 104 that are alternately stacked may then be completed.

When the first fluorine-containing layer 122 and the first blocking layer 132A are formed before forming the gate conductive layer 104, the semiconductor memory device in FIG. 6 may be formed.

The gate conductive layer 104 that is remaining on the side wall of the slit trench 112 may be etched to divide the gate conductive layer 104 along the third direction D3. A slit spacer 114 may be formed on both sidewalls of the slit trench 112. The slit spacer 114 may include an insulation layer.

The source sacrificial layer 202 of the preliminary source layer 200 may be removed through the slit spacer 114. The memory layer 130 that is exposed through the removed source sacrificial layer 202 may be etched to expose the channel layer 140.

The third source layer SL3 may be formed in a space that is formed by removing the source sacrificial layer 202. The third source layer SL3 may be electrically connected to the channel layer 140. The third source layer SL3 may include a doped semiconductor layer. For example, the third source layer SL3 may include an N type doped silicon layer.

A slit layer 116 may then be formed in the slit trench 112. The slit layer 116 may include a conductive layer. Alternatively, the slit layer 116 may include an insulation layer.

As a result, the slit structure 110 may be completed. The slit structure 110 may include the source layer SL, the slit trench 112, the slit spacer 114 and the slit layer 116. The source layer SL may include the first source layer SL1, the third source layer SL3, and the second source layer SL2 that are sequentially stacked.

Following processes including a process for forming a bit line may be performed to complete the semiconductor memory device.

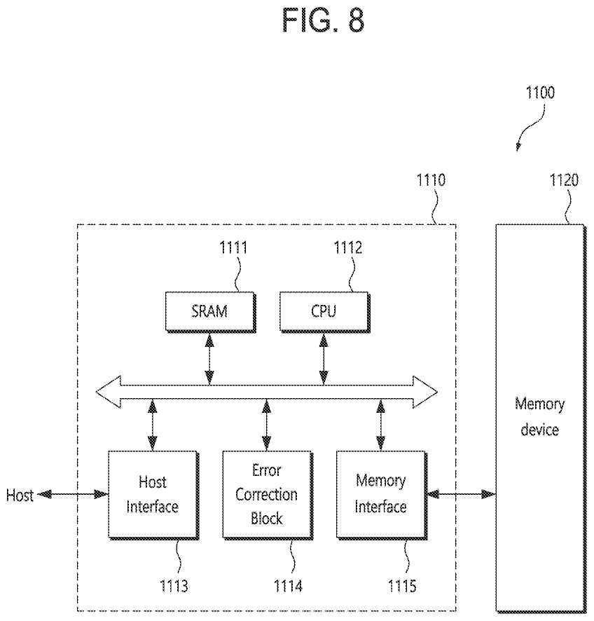

FIG. 8 is a block diagram illustrating a memory system memory device in accordance with example embodiments.

Referring to FIG. 8, a memory system 1100 may include a memory device 1120 and a memory controller 1110.

The memory device 1120 may include a gate stack structure, a plurality of channel holes, a memory layer, a first fluorine-containing layer, a channel layer and a second fluorine-containing layer. The gate stack structure may include an insulating layer with a plurality of fluorine ions and a gate conductive layer that are alternately stacked. The channel holes may be formed through the gate stack structure. The memory layer may be formed on a surface of the channel hole. The memory layer may include a first blocking layer, a charge-trapping layer, and a tunnel insulation layer that are sequentially stacked. The first fluorine-containing layer may be interposed between the gate stack structure and the first blocking layer. The channel layer may be formed on the tunnel insulation layer along the surface of the channel hole. The second fluorine-containing layer may be interposed between the channel layer and the tunnel insulation layer. The memory device 1120 may cure defects at the memory layer and structures making contact with the memory layer using the fluorine ions to suppress a trap caused by the defects and decrease generation probability of a tap auxiliary tunneling (TAT). Thus, when the memory device 1120 is exposed to a high temperature environment, programmed data might not be lost to improve reliability of the memory device 1120. The memory device 1120 may include a multi-chip package including a plurality of flash memory chips.

The memory controller 1110 may be configured to control the memory device 1120. The memory controller 1110 may include a static random access memory (SRAM) 1111, a central processing unit (CPU) 1112, a host interface 1113, an error correction block 1114 and a memory interface 1115. The SRAM 1111 may be used for an operational memory of the CPU 1112. The CPU 1112 may perform data exchanges of the memory controller 1110. The host interface 113 may include data exchange protocols coupled to the memory system 1100. The error correction block 1114 may detect and correct an error in data read from the memory device 1120. The memory interface 1115 may be interfaced with the memory device 1120. The memory controller 1110 may further include a read only memory (ROM) configured to store code data interfaced with a host.

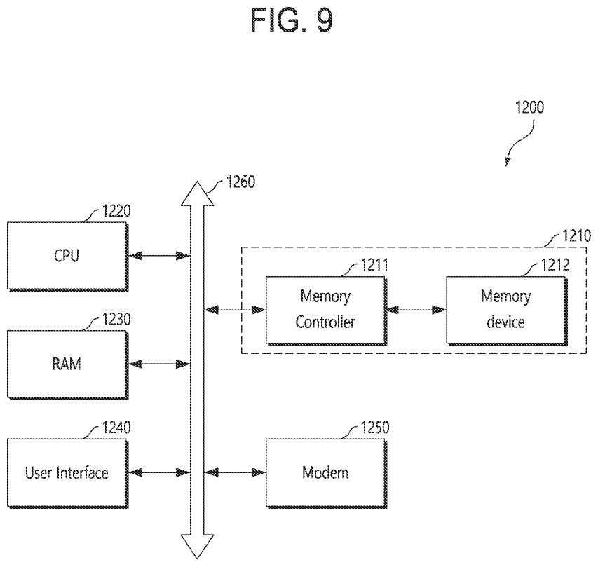

FIG. 9 is a block diagram illustrating a computing system in accordance with example embodiments.

Referring to FIG. 9, a computing system 1200 may include a CPU 1220, a random access memory (RAM) 1230, a user interface, a modem 1250 and a memory system 1210.

The memory system 1210 may include a memory device 1212 and a memory controller 1211. The memory device 1212 may include a gate stack structure, a plurality of channel holes, a memory layer, a first fluorine-containing layer, a channel layer and a second fluorine-containing layer. The gate stack structure may include an insulating layer with a plurality of fluorine ions and a gate conductive layer that are alternately stacked. The channel holes may be formed through the gate stack structure. The memory layer may be formed on a surface of the channel hole. The memory layer may include a first blocking layer, a charge-trapping layer, and a tunnel insulation layer that are sequentially stacked. The first fluorine-containing layer may be interposed between the gate stack structure and the first blocking layer. The channel layer may be formed on the tunnel insulation layer along the surface of the channel hole. The second fluorine-containing layer may be interposed between the channel layer and the tunnel insulation layer. The memory device 1212 may cure defects at the memory layer and structures making contact with the memory layer using the fluorine ions to suppress a trap caused by the defects and decrease generation probability of a tap auxiliary tunneling (TAT). Thus, when the memory device 1212 is exposed to a high temperature environment, programmed data might not be lost to improve reliability of the memory device 1212. The memory device 1212 may include a multi-chip package including a plurality of flash memory chips.

The above described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications are obvious in view of the present disclosure and are intended to fall within the scope of the appended claims.

What is claimed is:

1. A semiconductor memory device comprising:
a gate stack structure with an insulating interlayer and a gate conductive layer that are alternately stacked; and
a plurality of channel structures formed through the gate stack structure,
wherein each of the plurality of channel structures includes:
a fluorine-containing layer formed on surfaces of channel holes, formed in the gate stack structure, for forming the plurality of channel structures;
a first blocking layer formed on the fluorine-containing layer along the surface of the channel hole; and
a charge-trapping layer formed on the first blocking layer along the surface of the channel hole.

2. The semiconductor memory device of claim 1, further comprising a second blocking layer interposed between the first blocking layer and the charge-trapping layer, the second blocking layer including an insulating layer with a plurality of fluorine ions.

3. The semiconductor memory device of claim 2, wherein the first blocking layer and the second blocking layer comprise different oxide layers,
wherein the first blocking layer comprises a metal oxide layer, and
wherein the second blocking layer comprises a semiconductor oxide layer with the fluorine ions.

4. The semiconductor memory device of claim 1, wherein the first blocking layer comprises at least one component that is included in the fluorine-containing layer.

5. The semiconductor memory device of claim 1, wherein the first blocking layer comprises a metal oxide layer,
wherein the fluorine-containing layer comprises a metal oxyfluoride layer, and
wherein the first blocking layer and the fluorine-containing layer comprises a same metal component.

6. The semiconductor memory device of claim 5, wherein the first blocking layer comprises an aluminum oxide layer (Al₂O₃), and
wherein the fluorine-containing layer comprises an aluminum oxyfluoride layer (AlOxFy).

7. The semiconductor memory device of claim 1, wherein the insulating interlayer comprises an insulation layer with a plurality of fluorine ions.

8. A semiconductor memory device comprising:
a gate stack structure with an insulating interlayer and a gate conductive layer that are alternately stacked; and
a plurality of channel structures formed through the gate stack structure,
wherein each of the plurality of channel structures includes:
a charge-trapping layer formed on a surface of a channel hole, among a plurality of channel holes, formed in the gate stack structure to form the plurality of channel structures;
a tunnel insulation layer formed on the charge-trapping layer along the surface of the channel hole;
a fluorine-containing layer formed on the tunnel insulation layer along the surface of each of the channel holes; and
a channel layer formed on the fluorine-containing layer along the surface of the channel hole.

9. The semiconductor memory device of claim 8, wherein the tunnel insulation layer comprises an oxide layer, an oxide layer with a plurality of fluorine ions, or an oxynitride layer with a plurality of fluorine ions.

10. The semiconductor memory device of claim 8, wherein the channel layer comprises at least one component that is included in the fluorine-containing layer.

11. The semiconductor memory device of claim 10, wherein the channel layer comprises a silicon layer, and
wherein the fluorine-containing layer comprises a fluoric silicon layer.

12. The semiconductor memory device of claim 8, wherein the insulating interlayer comprises an insulation layer with a plurality of fluorine ions.

13. A semiconductor memory device comprising:
a gate stack structure with an insulating interlayer with a plurality of fluorine ions and a gate conductive layer that are alternately stacked; and
a plurality of channel structures formed through the gate stack structure,
wherein the plurality of channel structures include:
a memory layer formed on a surface of a channel hole that is formed in the gate stack structure to form the plurality of channel structures, the memory layer including a first blocking layer, a charge-trapping layer, and a tunnel insulation layer that are sequentially stacked;
a first fluorine-containing layer interposed between the gate stack structure and the first blocking layer;
a channel layer formed on the tunnel insulation layer along the surface of the channel hole; and
a second fluorine-containing layer interposed between the channel layer and the tunnel insulation layer.

14. The semiconductor memory device of claim 13, further comprising a second blocking layer interposed between the first blocking layer and the charge-trapping layer, the second blocking layer including an insulating layer with a plurality of fluorine ions.

15. The semiconductor memory device of claim 14, wherein the first blocking layer and the second blocking layer comprise different oxide layers,
wherein the first blocking layer comprises a metal oxide layer, and
wherein the second blocking layer comprises a semiconductor oxide layer with the fluorine ions.

16. The semiconductor memory device of claim 13, wherein the first blocking layer comprises at least one component that is included in the first fluorine-containing layer.

17. The semiconductor memory device of claim 13, wherein the first blocking layer comprises a metal oxide layer,
wherein the first fluorine-containing layer comprises a metal oxyfluoride layer, and
wherein the first blocking layer and the first fluorine-containing layer comprises a same metal component.

18. The semiconductor memory device of claim 13, wherein the tunnel insulation layer comprises an oxide layer, an oxide layer with a plurality of fluorine ions, or an oxynitride layer with a plurality of fluorine ions.

19. The semiconductor memory device of claim 13, wherein the channel layer comprises at least one component that is included in the second fluorine-containing layer.

20. The semiconductor memory device of claim 19, wherein the channel layer comprises a silicon layer, and
wherein the second fluorine-containing layer comprises a fluoric silicon layer.

21. A method of manufacturing a semiconductor memory device, the method comprising:
forming a stack structure with an insulating interlayer and a gate conductive layer that are alternately stacked;
selectively etching the stack structure to form a plurality of channel holes;
sequentially forming a first fluorine-containing layer and a first block layer on a surface of each of the channel holes;
sequentially forming a tunnel insulation layer and a charge-trapping layer on the first blocking layer along the surface of the channel hole;
performing a surface treatment on a surface of the tunnel insulation layer to absorb a plurality of fluorine ions on a surface of the tunnel insulation layer;
forming a second fluorine-containing layer on the tunnel insulation layer on which the surface treatment has been performed, along the surface of the channel hole; and
forming a channel layer on the second fluorine-containing layer along the surface of the channel hole.

22. The method of claim 21, further comprising forming a second blocking layer on the first blocking layer along the surface of the channel hole, the second blocking layer including an insulating layer with a plurality of fluorine ions.

23. The method of claim 22, wherein the first blocking layer and the second blocking layer comprise different oxide layers,
wherein the first blocking layer comprises a metal oxide layer, and
wherein the second blocking layer comprises a semiconductor oxide layer with the fluorine ions.

24. The method of claim 21, wherein the insulating interlayer comprises an insulation layer with a plurality of fluorine ions.

25. The method of claim 21, wherein the first blocking layer comprises at least one component that is included in the first fluorine-containing layer.

26. The method of claim 21, wherein the first blocking layer comprises a metal oxide layer,
wherein the first fluorine-containing layer comprises a metal oxyfluoride layer, and
to wherein the first blocking layer and the first fluorine-containing layer comprises a same metal component.

27. The method of claim 26, wherein the first blocking layer comprises an aluminum oxide layer (Al₂O₃), and
is wherein the first fluorine-containing layer comprises an aluminum oxyfluoride layer (AlOxFy).

28. The method of claim 21, wherein the surface treatment comprises a fluorine plasma treatment.

29. The method of claim 28, wherein the tunnel insulation layer comprises an oxide layer or an oxynitride layer.

30. The method of claim 21, wherein the surface treatment comprises an annealing process that uses a mixed gas of an inert gas and a fluorine gas, and
wherein the annealing process is performed at a temperature that is higher than 400° C. and a pressure that is higher than atmospheric pressure.

31. The method of claim 30, wherein the tunnel insulation layer comprises an oxide layer with a plurality of fluorine ions or an oxynitride layer with a plurality of fluorine ions.

32. The method of claim 21, wherein the channel layer comprises at least one component that is included in the second fluorine-containing layer.

33. The method of claim 32, wherein the channel layer comprises a silicon layer, and
wherein the second fluorine-containing layer comprises a fluoric silicon layer.
